(19) United States
(12) Patent Application Publication
(10) Pub. No.: US 2026/0066611 A1
(43) Pub. Date: Mar. 5, 2026

(54) OPTOELECTRONIC LIGHT SOURCE AND DATA GLASSES

(71) Applicants: ams-OSRAM International GmbH, Regensburg (DE); ams International AG, Jona (CH)

(72) Inventors: Alan LENEF, BELMONT, MA (US); Ioannis PAPADOPOULOS, LAUSANNE (CH); Anna BUTSCH, Regensburg (DE); Karsten AUEN, Regensburg (DE)

(73) Assignees: ams-OSRAM International GmbH, Regensburg (DE); ams International AG, Jona (CH)

(21) Appl. No.: 19/108,286

(22) PCT Filed: Sep. 4, 2023
(86) PCT No.: PCT/EP2023/074117

§ 371 Date: Mar. 3, 2025

Related U.S. Application Data
(60) Provisional application No. 63/413,402, filed on Oct. 5, 2022.
(60) Provisional application No. 63/487,901, filed on Mar. 2, 2023.

(51) Int. Cl. H01S 5/00; G02B 27/09; H01S 5/02255; H01S 5/02315; H01S 5/40

(52) U.S. Cl. CPC H01S 5/0071; G02B 27/0905; G02B 27/0922; G02B 27/0983; H01S 5/02255; H01S 5/02315; H01S 5/4012; H01S 5/4031; H01S 5/4093

(57) ABSTRACT

In one embodiment, the optoelectronic light source includes a first semiconductor laser configured to emit a first laser beam, and a redirecting optical element, wherein the first laser beam runs from the first semiconductor laser to a first primary reflection zone and further directly from the first primary reflection zone to a first secondary reflection zone of the redirecting optical element, directly after the first semiconductor laser, the first laser beam has an asymmetric beam cross-section, the redirecting optical element reduces an asymmetry of the beam cross-section of the first laser beam, and with a tolerance of at most 45°, directly after the first semiconductor laser the first laser beam (L1) may run antiparallel relative to the first laser beam directly after the first secondary reflection zone.

### CROSS-REFERENCE TO RELATED APPLICATIONS

The present application is the national stage entry of International Patent Application No. PCT/EP2023/074117, filed on Sep. 4, 2023, and published as WO 2024/074254 A1 on Apr. 11, 2024, which claims the benefit of U.S. Provisional Patent Application Nos. 63/413,402 filed on Oct. 5, 2022, and 63/487,901 filed on Mar. 2, 2023, all of which are incorporated by reference herein in their entireties.

### FIELD OF THE INVENTION

An optoelectronic light source is provided. Data glasses comprising such an optoelectronic light source are also provided.

### BACKGROUND OF THE INVENTION

Documents WO 2020/212221 A1 and WO 2010/069282 A2 refer to arrangements of semiconductor lasers.

An object to be achieved is to provide an optoelectronic light source that has improved beam combination characteristics.

This object is achieved, inter alia, by an optoelectronic light source and by data glasses as defined in the independent patent claims. Exemplary further developments constitute the subject-matter of the dependent claims.

### SUMMARY OF THE INVENTION

In at least one embodiment, the optoelectronic light source comprises:
a first semiconductor laser configured to emit a first laser beam and optionally arranged on a mounting platform,
a redirecting optical element configured to redirect the first laser beam, wherein
the redirecting optical element comprises a first primary reflection zone and a first secondary reflection zone,
the first laser beam, for example, directly runs from the first semiconductor laser to the first primary reflection zone and further directly from the first primary reflection zone to the first secondary reflection zone, or one or a plurality of combining optical elements are placed between the first semiconductor laser and the redirecting optical element,
directly after the first semiconductor laser, the first laser beam has an asymmetric beam cross-section, by means of the redirecting optical element an asymmetry of the beam cross-section of the first laser beam is reduced, and
with a tolerance of at most 45°, directly after the first semiconductor laser and/or directly before the redirecting optical element the first laser beam runs antiparallel relative to the first laser beam directly after the first secondary reflection zone.

In mobile, near-to-eye augmented reality/virtual reality (AR/VR) head up displays, and other low-power projection applications, high display luminance can best be achieved using red, green, and blue (RGB) laser diode (LD) sources. Such sources have lowest possible étendue so that coupling into an optical AR/VR optical system has highest efficiency and permits highest potential resolution of formed retinal images. In many cases, collinear and collimated RGB laser beams are highly desirable, especially in systems employing micro-electromechanical (MEM) mirrors to create images by scanned laser beams. These are often called laser-beam scanning (LBS) image generation systems.

To make compact RGB collimated laser sources that are only a few millimeters on a side to fit inside an AR/VR glasses projection system is quite challenging. For best optical performance, red, green, and blue LDs couple into their own collimating optics, followed by beam combination optics, such as multiple dichroic mirrors, and sometimes an additional deflecting mirror to redirect the light to the desired direction. The collimating optics in particular can require significant space to properly collimate slow and fast axes of edge emitting LDs (EELs) typically used in these sources. Such optics are also usually based on small refractive elements which can be expensive to produce. Such elements may also increase optical path length due to the slower beam divergence within the optical material. In other cases, the beam combination may be performed first on uncollimated laser beams, followed by a set of collimating optics. This approach in particular may require a complex collimating lens to have low chromatic aberration and will be limited by the different divergence and astigmatism behavior of the red, green, and blue LDS.

To solve the problem of using expensive and larger than desired refractive optical elements for collimating laser light from the LDs, herein a single curved mirror is employed to perform both circularization and collimation of the laser light. By using a folded configuration, the overall package can be very compact. This configuration also has two focusing surfaces which have enough degrees of freedom to collimate both fast and slow axes of EELs, including the generation of a circular final wavefront. Herein it is also considered using the beam-combination first approach using a similar folded mirror configuration which will have negligible chromatic aberration.

Other approaches are based on combining LD outputs using photonic integrated circuits (PICs). For example, LDs may be arranged parallel to each other in a plane, where one or more focusing lenses are used to focus each laser into the inputs of the PLC. Another approach is to fabricate PLCs using silver ion exchange in certain glasses. This leads to buried structures which have modest confinement capabilities due to the refractive index variation of Δn˜0.1. Possibly, RGB fields are not physically combined, but simply come in close proximity at an output side, with ˜20 μm separation. In these PIC approaches, cost is potentially quite high due to the need to actively align the laser diodes to the waveguide inputs with sub-micron precision. There can also be significant feedback issues from the PIC to the LD, causing suppression of a broader band LD output which reduces coherent artifact formation in laser-based AR/VR systems.

Using established low-cost fabrication methods such as precision stamping, high quality, precision mirrors can be fabricated for the desired configurations.
1. The light source described herein solves the problem of current collimating modules being too large by using a folded mirror approach. This is accomplished, for example, by two technical features:
a) It combines two optical functions, that is, slow and fast axis collimation, into a single optic. This eliminates using two completely separated mirrors or lenses for each collimation axis. Use of a single focusing reflective surface, that is, only a single reflection, does not have enough degrees of freedom to both collimate and circularize the emission from EELs in many cases.
b) The optical path is folded, reducing the overall lateral footprint size.
c) Using reflective rather than refractive optics reduces the overall optical path length due to the light diverging more rapidly in air versus a lens material.
2. In the case of a collimating optic placed after beam combination, the folded mirror approach eliminates chromatic aberration that is problematic with previous refractive optic solutions.

In addition, some of the embodiments have additional technical features that further help solve the problems stated above:
1. The mirror surfaces can be coated to enhance reflectivity and further increase efficiency.
2. Instead of curved mirrors, one can replace one or both of the curved mirror surfaces with flat angled reflective meta-optic surfaces which may improve beam quality.

Summarizing, the light source described herein goes ahead with one or several technical advantages:
a) This eliminates using two separated mirrors for each collimation axis. This is much simpler and reduces fabrication and alignment costs.
b) The package size can be reduced.
c) Reflective optics fabricated by precision stamping can be low cost and very high precision compared to molded/polished refractive parts is achievable.
d) Chromatic aberration is eliminated.
e) Reflective optics are especially useful in very high power applications.

While the primary application of the light sources described herein is for AR/VR glasses, it can be used for other applications requiring the output from multiple EELs or VCSELs as well. In many cases, the AR/VR system of consideration is for a scanning micro-electromechanical (MEM) mirror system.

The redirecting optical element described herein can be made by one of several processes. This includes, for example, precision stamping, diamond machining and mechanical and/or electrochemical polishing, precision molding of plastic or metal, followed by coating of dielectric or enhanced metallic mirror coatings, and other methods.

According to at least one embodiment, the optoelectronic light source further comprises a second semiconductor laser configured to emit a second laser beam and also arranged on the mounting platform.

According to at least one embodiment, the redirecting optical element further comprises a second primary reflection zone and a second secondary reflection zone, the second primary reflection zone and the second secondary reflection zone are configured to reduce a beam asymmetry of the second layer beam. That is, the redirecting optical element is configured to handle the second layer beam in the same way as the first laser beam.

According to at least one embodiment, there is at least one further semiconductor laser, like a third semiconductor laser for emitting a third laser beam. That is, all the first, second and third laser beams can be handled by the redirecting optical element in the same manner. The features disclosed for the second semiconductor laser can equally or analogously apply for the further semiconductor laser, like the third semiconductor laser.

According to at least one embodiment, with a tolerance of at most 45° or of at most 15° or of at most 5°, directly after the second semiconductor laser the second laser beam runs antiparallel relative to the second laser beam directly after the second secondary reflection zone. The same may apply for the first and/or third laser beam.

According to at least one embodiment, with a tolerance of at most 45° or of at most 15° or of at most 5°, after passing the redirecting optical element, the first laser beam, the second laser beam and/or the third laser beam run in a common plane.

According to at least one embodiment, beam diameters of the first, second and/or third laser beams at the respectively assigned primary reflection zone amount to at least 0.2 mm or to at least 0.4 mm or to at least 1.0 mm. For example, these diameters are at most 5 mm or at most 2 mm. Hence, the redirecting optical element can be configured to collimate or focus the first, second and/or third laser beam with a remaining divergence angle of at most 5° or of at most 2° or of at most 1°.

If the respective area or cross-section is not of exact circular fashion, then for the assigned analogous diameter D from the formula for a circular area A_{circular}=π(D/2)² it applies for a non-circular area: D=(4A/π)^{1/2}, wherein A is an area content of the respective non-circular area or cross-section. Preferably, the respective area or cross-section is of nearly circular fashion. ‘Nearly circular’ may mean that a quotient of a longest chord divided by a shortest chord through a centroid of the respective area or cross-section is at most ten or is at most five or is at most two or is at most 1.5 or is at most 1.2. These values may also be referred to as eccentricity.

According to at least one embodiment, the optoelectronic light source further comprises one or a plurality of combining optical elements. For example, the combining optical element or at least one of the combining optical elements or a combination of combining optical elements is arranged directly after the first and/or second and/or third semiconductor lasers. Alternatively or additionally, the at least one combining optical element can be arranged directly before the redirecting optical element.

According to at least one embodiment, the combining optical element is configured to merge the first and second laser beams into a common laser beam. If there is a third laser beam from a third semiconductor laser, the third laser beam can also be merged into the common laser beam. Hence, the common laser beam includes the first and second laser beams and optionally also the third laser beam.

According to at least one embodiment, the combining optical element is a transmissive optical element. Otherwise, the combining optical element is a reflective optical element, or also a combination of a transmissive optical element and a reflective optical element.

According to at least one embodiment, optical path lengths of the first and second laser beams, and optionally of the third laser beam, from the respective semiconductor lasers to the redirecting optical element are all the same. This applies, for example, with a tolerance of at most 10% or of at most 5% of the largest optical path length from the respective semiconductor laser to the redirecting optical element. The optical path lengths are the respective integrals over the geometric lengths and the refractive indices for the associated laser beam from the respective semiconductor laser to, for example, the redirecting optical element.

According to at least one embodiment, the combining optical element conserves a direction of the first laser beam. That is, a direction of the first laser beam is not changed by the combining optical element. Hence, the first laser beam may travel straightly through the combining optical element.

According to at least one embodiment, the first semiconductor laser is arranged on a front side of the combining optical element. For example, the front side is opposite the redirecting optical element. The front side may be a plane face of the combining optical element.

According to at least one embodiment, the second semiconductor laser, and optionally the third semiconductor laser, is arranged on a lateral side of the combining optical element. For example, the lateral side runs in parallel with the first laser beam within the combining optical element. This applies, for example, with a tolerance of at most 30° or of at most 10° or of at most 5°. In other words, directly after the second semiconductor laser the second laser beam can run perpendicular to the first laser beam. The same may apply for the third laser beam.

According to at least one embodiment, all the semiconductor lasers are arranged on the same common front side. In this case, the front side and/or an exit side of the combining optical element may be oriented obliquely relative to an optical axis of the redirecting optical element.

According to at least one embodiment, the common laser beam is formed within the combining optical element. For example, the combined laser beam begins in an interior of the combining optical element.

According to at least one embodiment, the combining optical element comprises a first mirror which is an internal mirror. For example, the first mirror is configured to transmit the first laser beam and to reflect the second laser beam.

Analogously, there can be a second mirror for the third laser beam which transmits the first and second laser beams and which reflects the third laser beam.

According to at least one embodiment, the combining optical element consists only of condensed matter. For example, the combining optical element is a block of solid material including and/or being provided with the at least one mirror.

According to at least one embodiment, the combining optical element has no or only negligible effect on a beam divergence. That is, the combining optical element can be considered as or can be equivalent to a plane-parallel plate or a plane mirror, with respect to beam collimation. For example, all relevant faces of the combining optical element are of overall plane construction.

According to at least one embodiment, at least one of the respective primary reflection zone or secondary reflection zone is of curved shape. Both reflection zones can be of curved shape.

According to at least one embodiment, one of the primary reflection zone or the secondary reflection zone is of planar shape.

According to at least one embodiment, both the respective primary reflection zone and the corresponding secondary reflection zone are mirrors having a main curvature and a minor curvature along perpendicular directions, the main curvatures are oriented along main directions perpendicular to one another with a tolerance of at most 30° or of at most 10° or of at most 3° or of at most 1°. The main curvatures and minor curvatures corresponding to one another differ from one another by at least a factor of five or by at least a factor of ten or by at least a factor of 100, wherein a radius of curvature of the main curvature is smaller than that of the corresponding minor curvature. For example, the minor curvature can be zero or virtually zero so that the corresponding radius of curvature is infinite.

According to at least one embodiment, the first, second and/or third semiconductor layer is an edge-emitting laser.

According to at least one embodiment, one of the corresponding primary reflection zone and secondary reflection zone is configured for fast-axis collimation, and the other one of the primary and the secondary reflection zones is configured for slow-axis collimation. For example, the primary reflection zone is for fast-axis collimation and the secondary reflection zone is for slow-axis collimation. Otherwise, the primary reflection zone is for slow-axis collimation and the secondary reflection zone is for fast-axis collimation.

According to at least one embodiment, the redirecting optical element is a monolithic mirror element. That is, all the reflection zones are fixed relative to one another. This can mean that the reflection zones cannot be adjusted relative to one another. For example, the redirecting optical element comprises a block in which all the reflection zones are formed.

According to at least one embodiment, at least one of the respective primary reflection zone or the secondary reflection zone is a polynomial mirror or a parabolic mirror.

According to at least one embodiment, at least one of the respective primary reflection zones or secondary reflection zones is on average of planar shape and comprises at least one meta-optical structure, like meta-reflectors. The meta-optical structures have a size of less than the peak vacuum wavelength of the assigned laser beam.

Data glasses are additionally provided. The data glasses comprise one of a plurality of the semiconductor light sources as indicated in connection with at least one of the above-stated embodiments. Features of the semiconductor light source are therefore also disclosed for the data glasses and vice versa.

In at least one embodiment, the data glasses are configured for virtual reality or augmented reality applications, comprising at least one optoelectronic light source, an imaging unit downstream of the optoelectronic light source, and a picture-making element downstream of the imaging unit. The optoelectronic light source is configured to illuminate the picture-making element by means of the imaging unit so that a picture can be produced by means of the picture-making element.

### BRIEF DESCRIPTION OF THE DRAWINGS

A semiconductor light source and data glasses described herein are explained in greater detail below by way of exemplary embodiments with reference to the drawings. Elements which are the same in the individual figures are indicated with the same reference numerals. The relationships between the elements are not shown to scale, however, but rather individual elements may be shown exaggeratedly large to assist in understanding.

In the figures:

FIG. 1 is a schematic sectional view of an exemplary embodiment of a semiconductor light source described herein,

FIG. 2 is a schematic representation of an asymmetry of beam cross-sections at different positions of laser beams in semiconductor light source described herein,

FIG. 3 is a schematic perspective view of an exemplary embodiment of a semiconductor light source described herein,

FIG. 4 is a schematic representation of curvatures of reflection zones in semiconductor light source described herein,

FIGS. 5 and 6 are schematic perspective views of exemplary embodiments of semiconductor light sources described herein,

FIG. 7 is a schematic perspective view of an exemplary embodiment of data glasses comprising semiconductor light sources described herein, and

FIGS. 8 to 13 in each case in the upper parts schematic side views and in the lower parts schematic top views of exemplary embodiments of semiconductor light sources described herein.

### DETAILED DESCRIPTION

FIG. 1 illustrate an embodiment of a semiconductor light source 1. The semiconductor light source 1 comprises a first semiconductor laser 21 configured, for example, to emit visible light that propagates in a first laser beam L1. Moreover, optically downstream of the semiconductor laser 21 there is a redirecting optical element 4. The redirecting optical element 4 comprises a first primary reflection zone 411 next to the semiconductor laser 21 and a first secondary reflection zone 412 remote from the semiconductor laser 21. Optionally, there are no further optical elements until the first secondary reflection zone 412.

The first semiconductor laser 21 is arranged on a mounting platform 3. It is possible that the mounting platform 3 and the redirecting optical element 4 have fix positions relative to one another. For example, the redirecting optical element 4 and the mounting platform 3 are attached to each other in a mechanically rigid manner.

For example, the reflection zones 411, 412 are shaped two-dimensional reflecting curved surfaces. The first surface, that is, the primary reflection zone 411, provides partial shaping of the laser wavefront of the first laser beam L1, reflecting the partially shaped light onto a second surface, that is, the secondary reflection zone 412, which completes the beam shaping. The reflecting surfaces 411, 412 may have a continuous shape, but a bridge between the two surfaces 411, 412 can have discontinuities between them in general as the bridge may not have any optical function.

After the second surface 412, the first laser beam L1 travels antiparallel compared with directly after the semiconductor laser 21. After the second surface 412, the first laser beam L1 may be a bundle of parallel rays or may also be a bundle of convergent rays.

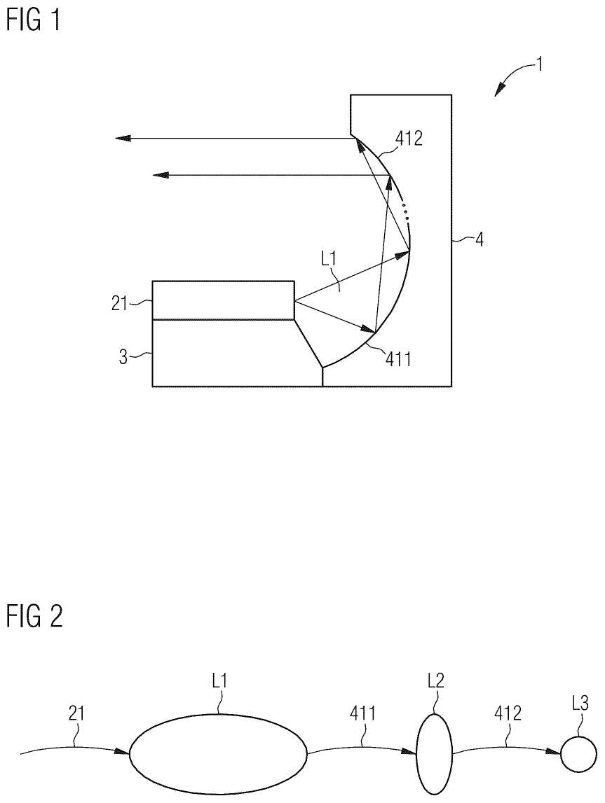

In FIG. 2 it is shown that a beam asymmetry or eccentricity of the first laser beam L1 coming from the first semiconductor laser 21 is step-wise reduced by means of the surfaces 411, 412 so that a circular or nearly circular beam can be obtained after passing the redirecting optical element 4.

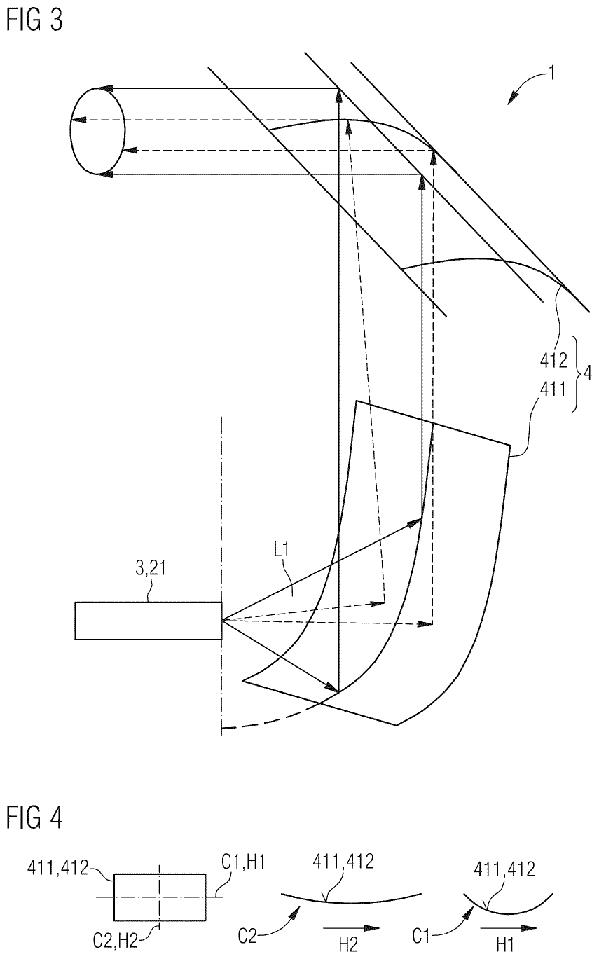

FIG. 3 shows another version of the semiconductor light source 1. Here, the first surface 411 collimates the fast EEL axis, consisting of a vertically aligned one-dimensional parabolic surface. A vertex of the parabola is aligned with an emission point of the first laser 21, thus collimating the fast axis rays. The second surface 412 may consist of a one-dimensional parabolic surface, too, but of lower curvature and oriented in the horizontal direction. This collimates the slow axis.

More generally, the second or both surfaces 411, 412 can have a curvature defined by a parabolic and/or a polynomial surface. By appropriate choice of curvatures and distances between the centers of the surfaces 411, 412, one can obtain a collimated circular beam, much as one would obtain with refractive optics.

Otherwise, the same as to FIGS. 1 and 2 may also apply to FIG. 3, and vice versa.

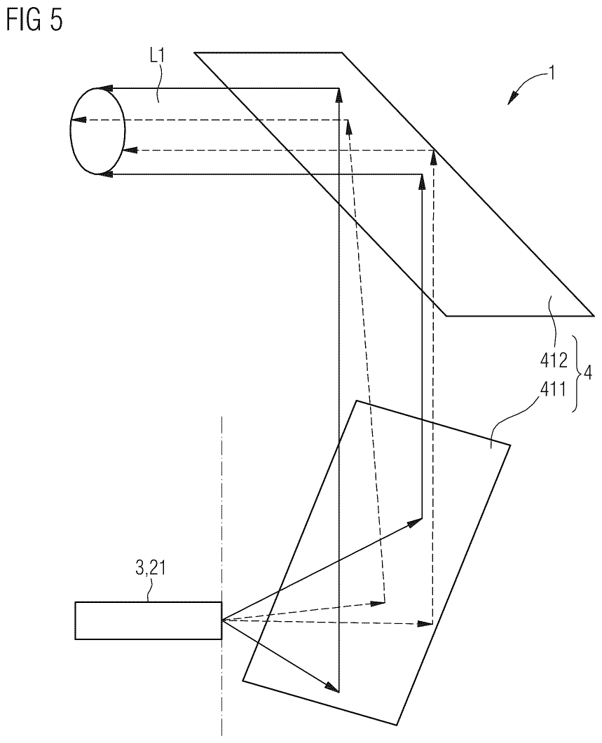

In FIG. 4, the curvatures are explained in more detail. In FIG. 4, left part, one of the surfaces 411, 412 is schematically illustrated. Seen in top view, for example, along an optical axis of the incoming first laser beam L1, the reflecting surface 411, 412 has a first main direction H1 and a second main direction H2 which are perpendicular to one another. Along the direction H1, there is a main curvature C1, seen in cross-section, and along the direction H2 there is a minor curvature C2, see the middle and right parts of FIG. 4. As can be seen, the curvatures C1, C2 differ significantly from one another and the curvature C2 is the smaller one. It is possible, like in FIG. 3, that the minor curvature C2 is indeed zero so that in the respective cross-section there is a straight line.

Otherwise, the same as to FIGS. 1 to 3 may also apply to FIG. 4, and vice versa.

In the embodiment shown in FIG. 5, the two reflecting surfaces 411, 412 are replaced by two flat reflecting surfaces that have a meta-optic structures applied to each surface to function as fast and slow axis collimators. The meta-surfaces shape the incoming wavefront by introducing phase shifts (up to modulo 2π, generally) to cause one-dimensional or two-dimensional astigmatic collimation or wavefront shaping of the first laser beam L1. The two planar substrates that provide the surfaces 411, 412 can also be coated to provide high reflectivity performance for overall zero-order beam directing.

Otherwise, the same as to FIGS. 1 to 4 may also apply to FIG. 5, and vice versa.

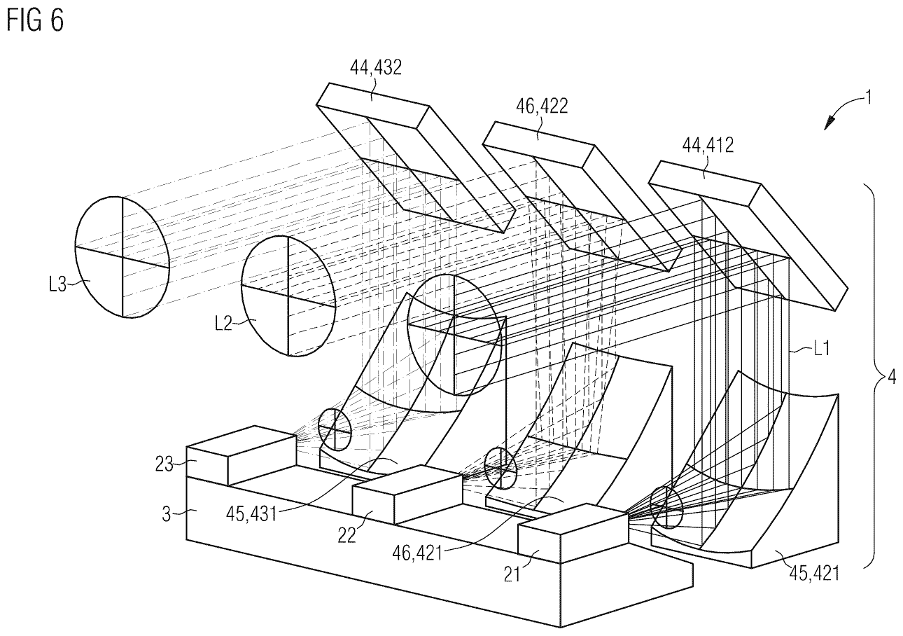

The semiconductor light source 1 of FIG. 6 further comprises a second semiconductor laser 22 that emits a second laser beam L2 and a third semiconductor laser 23 that emits a third laser beam L3. For example, the lasers 21, 22, 23 emit red, green and blue light, for example, independent of one another. For each one of the lasers 21, 22, 23, the redirecting optical element 4 comprises a primary reflection zone 411, 421, 431 and a correspondingly assigned secondary reflection zone 412, 422, 432.

All the reflection zones 411, 421, 431, 412, 422, 432 can monolithically be integrated in the redirecting optical element 4 so that the reflection zones 411, 421, 431, 412, 422, 432 are fixed relative to one another.

It is possible that the lasers 21, 22, 23 have different emission characteristics, that is, that the laser beams L1, L2, L3 directly after the respective laser 21, 22, 23 differ in their divergence and/or eccentricity. By having two separate reflection zones 411, 421, 431, 412, 422, 432 for each one of the lasers 21, 22, 23, this can efficiently be taken into account.

For example, the first mirrors 411, 431 are two-dimensional parabolic mirrors that collimate the respective beams L1, L3, and the second mirrors 413, 433 are flat, without any optical power. The mirrors 421, 422 for the second laser beam L2, which is, for example, green light, are instead polynomial mirrors. Hence, the green light can accurately be handled by the redirecting optical element 4 while the laser beams L1, L3, for example, blue and red light, can be handled more cost efficiently.

A combination of the embodiments of FIGS. 1, 3 and 5 as well as 6 can be applied in different ways to different wavelengths of an RGB laser package, so that eventually some wavelengths have a higher resolution than others, for example. Especially, red and blue have lower resolution and green has higher resolution.

All the aspects disclosed above for the first primary reflection zone 411 and the first secondary reflection zone 412 apply analogously for the second and third reflection zones 421, 422, 431, 432.

Otherwise, the same as to FIGS. 1 to 5 may also apply to FIG. 6, and vice versa.

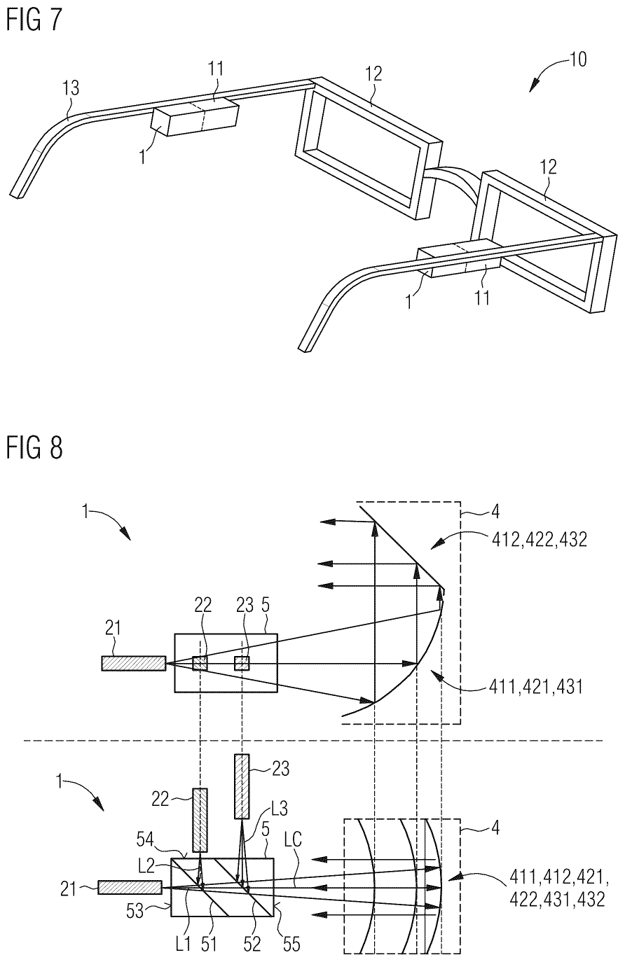

In FIG. 7, an exemplary application for the above-described optoelectronic light sources 1 is illustrated. Thus, data glasses 10 comprise two of the optoelectronic light sources 1 arranged at a glasses frame 13. An imaging unit 11 is arranged downstream of the optoelectronic light source 1, for example, in a common housing. A picture-making element 12 is downstream of the imaging unit 11.

The optoelectronic light sources 10 illuminate the picture-making elements 12 by means of the associated imaging units 11 so that pictures can be produced by means of the picture-making elements 12.

For example, the at least one picture-making element 12 is a screen or a two-dimensional waveguide or a holographic mirror. As an option, there can be relay optics between the imaging unit 11 and the at least one assigned picture-making element 12, not illustrated.

For example, the imaging unit 11 is a microelectromechanical system (MEMS) mirror. Otherwise, the imaging unit 11 can comprise at least one liquid crystal on silicon (LCoS) element. For example, there is one common LCOS element for all the semiconductor lasers 21, 22, 23 of one light source 10, or there is one LCOS element per semiconductor laser 21, 22, 23.

Otherwise, the same as to FIGS. 1 to 6 may also apply to FIG. 7, and vice versa.

In FIG. 6, for each one of the semiconductor lasers 21, 22, 23 there are two of the reflection zones 411, 412, 421, 422, 431, 432 so that there are six of the reflection zones 411, 412, 421, 422, 431, 432. Contrary to that, in the following in connection with FIGS. 8 to 13 it is illustrated that in each case a combining optical element 5 is, for example, directly between the semiconductor lasers 21, 22, 23 and the redirecting optical element 4. Other than shown, it is possible that there is more than one combining optical element 5, however, in FIGS. 8 to 13 just one combining optical element 5 is illustrated for simplicity.

That is, in the device of FIG. 6 a folded 2-in-1 mirror 4 is used, that combines two optical functions, namely fast and slow axis non-refractive collimation, into a single optics. Hence, circularization of elliptic beam shapes is possible with a single optical element 4. Thus, a reduction of optical path lengths and/or smaller footprints and/or miniaturization is possible. Further, less beam-shaping optical elements are required and lower production cost can be achieved, and active alignment efforts are reduced.

In the devices 1 as described below in connection with FIGS. 8 to 13, beam combination is performed prior to collimation, and beam combination can be realized in various ways. Thus, due to achromaticity of collimating mirrors combined beams can be collimated with the single optics 4, assuming negligible differences in astigmatism and divergence of red, green and blue semiconductor lasers 21, 22, 23, for example, so that less collimating zones are required and so that there are reduced alignment efforts.

Consequently, an output of collimated and overlapped laser beams, which can be of different colors or of the same color, is achieved with only two separate optical elements 4, 5, that is, the beam combiner element 5 and the element 4 comprising just two different reflective surfaces, for example. Thus, a reduction of a package size and a compact solution can be realized. Further, a reduction of alignment effort and a higher throughput in production are possible. Consequently, there is a high cost-down potential. Moreover, reflective optics can be used which are of advantage in high power applications.

In FIG. 8 it is shown that the combining optical element 5 is a cube of a solid material in which there is a first mirror 51 and a second mirror 52. The first semiconductor laser 21, which, for example, is configured to emit blue light, is located at a front side 53 of the combining optical element 5. The first beam L1 runs straightly through the combining optical element 5 towards an exit side 55. The exit side 55 faces the redirecting optical element 4. For example, the front side 53 and the exit side 55 are plane faces being in parallel with each other.

The second semiconductor laser 22 and the optional third semiconductor laser 23 are located at a lateral side 54 of the combining optical element 5. The lateral side 54 may be perpendicular to the exit side 55 and can be a plane face, too. For example, the second semiconductor laser 22 emits green light and the third semiconductor laser 23 emits red light in operation of the device 1. The third semiconductor laser 23 can be more distant to the lateral side 54 than the second semiconductor laser 22 so that all optical paths of the laser beams L1, L2, L3 until the redirecting optical element 4 have the same length. Between the lasers 21, 22, 23 and the combining optical element 5 there can be a gap.

The first mirror 51 is transmissive for the first beam L1 and reflective for the second beam L2. The second mirror 52 is reflective only for the third beam L3 and transmissive both for the first beam L1 and the second beam L2. For example, the mirrors 51, 52 are dielectric multi-layer coatings applied to prismatic bodies attached to one another so that the combining optical element 5 is created. The prismatic bodies can all be of the same material, like a glass, and may be glued together using, for example, an organic adhesive. Thus, by means of the mirrors 51, 52 a combined laser beam LC is created that includes all the laser beams L1, L2, L3 which run in a congruent manner and/or share the same optical axis after being merged into the combined laser beam LC.

Thus, in the combining optical element 5 beam combination is done with dichroic beam splitters 51, 52. For example, an emission point of each semiconductor laser 21, 22, 23 is aligned to a virtual focal point of the redirecting optical element 4. Collimation in the redirecting optical element 4 can be done with concave reflective surfaces which can be of aspheric, parabola or free-form shape, or alternatively or additionally with reflecting metasurfaces.

For example, the single reflection zone 411, 421, 431 is for fast-axis collimation of all the beams L1, L2, L3, and the single reflection zone 412, 422, 432 is for slow-axis collimation of all the beams L1, L2, L3.

With this set-up, high efficiency can be achieved. Otherwise, the same as to FIGS. 1 to 7 may also apply to FIG. 8, and vice versa.

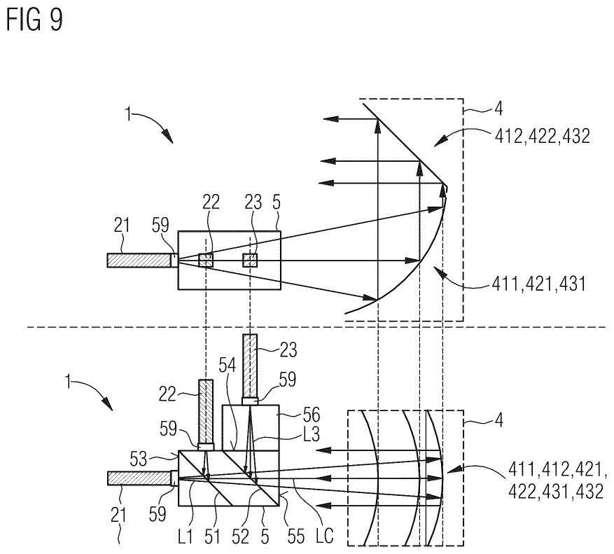

In the device 1 of FIG. 9, the semiconductor lasers 21, 22, 23 are directly attached to the combining optical element 5 by means of an adhesives 59. Hence, there is no free space between the semiconductor lasers 21, 22, 23 and the combining optical element 5, and the beams L1, L2, L3 travel in solid materials only until the exit side 55. Thus, Near-Field-Encapsulation, NFE, technology is used in the device 1 of FIG. 9 so that a non-hermetic packaging is enabled to be used instead of a hermetic packaging as possibly required in the device of FIG. 8, for example.

The adhesive 59 is, for example, an inorganic material such as a glass or at least one metal. Alternatively, the adhesive 59 is a plastic such as a silicone, poly-siloxane, poly-silazane or a silicone hybrid material, preferably a low-organic plastic. Poly-siloxane means that the material is built of —[O—SiR₂]ₙ-, in the case of poly-silazane of —[NH—SiR₂]ₙ-, wherein it is possible for different moieties R to be present in each case. Low-organic means, for example, that a proportion of organic constituents on the silicone, siloxane or silazane is not more than 30 percent by mass or 20 percent by mass and/or that, in particular in the case of a siloxane or silazane, a quotient of a number of carbon-containing moieties R and of n is at most 0.75 or at most 0.25. The mass proportion of the organic matter is determined in particular by asking the material. Less preferably, the adhesive 59 may be of an organic material such as an epoxy and/or a polymer of carbon-containing structural units.

Moreover, concerning the adhesive, reference is also made to document US 2020/0313399 A1, the disclosure content of which is hereby included by reference, especially concerning paragraphs 68 to 73, 87, 92, 101 and 102.

As an option, to enable equal path lengths of the laser beams L1, L2, L3 before becoming the common laser beam LC, there can be a distance adjustment piece 56 at the lateral side 54, for example, for the third semiconductor laser 23 which is located next to the redirecting optical element 4. For simplicity, the distance adjustment piece 56 is shown in FIG. 9 to be of cubic shape, but other shapes are also possible. The first and second semiconductor layers 21, 22 can be arranged at the front side 53 and at the lateral side 54, respectively, so that the laser beams L1, L2 have the same path length upon being merged by the first mirror 51.

Otherwise, the same as to FIG. 8 may also apply to FIG. 9, and vice versa.

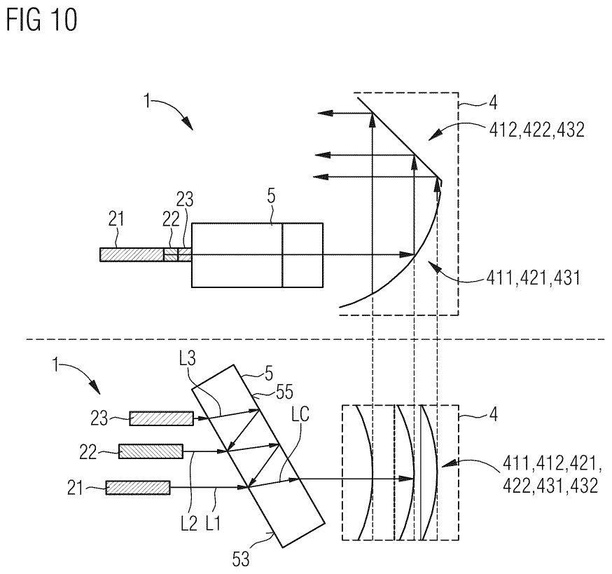

In FIG. 10 it is shown that the combining optical element 5 is of a single piece, like a plane-parallel plate. The combining optical element 5 is arranged in a tilted manner relative to the redirecting optical element 4. Accordingly, the third laser beam L3 is reflected twice at the exit side 55 and the second laser beam L2 is reflected there only once.

The second laser beam L2 enters the combining optical element 5 at the front side 53 where the third laser beam L3 is reflected, and the first laser beam L1 enters the front side 53 where both the third and second laser beams L3, L2 are reflected. With entrance of the first laser beam L1 into the combining optical element 5, the common laser beam LC is formed.

To achieve the desired reflection and transmission behavior, the combining optical element 5 can be provided with corresponding optical coatings at the front side 53 and at the exit side 55, respectively. It is possible that different places of the front side 53, for example, are provided with different optical coatings, like dielectric layer stacks.

Other than shown in FIG. 10, there can be distance adjustment pieces and/or adhesives as well, similar to what is shown in FIG. 9.

Otherwise, the same as to FIGS. 8 and 9 may also apply to FIG. 10, and vice versa.

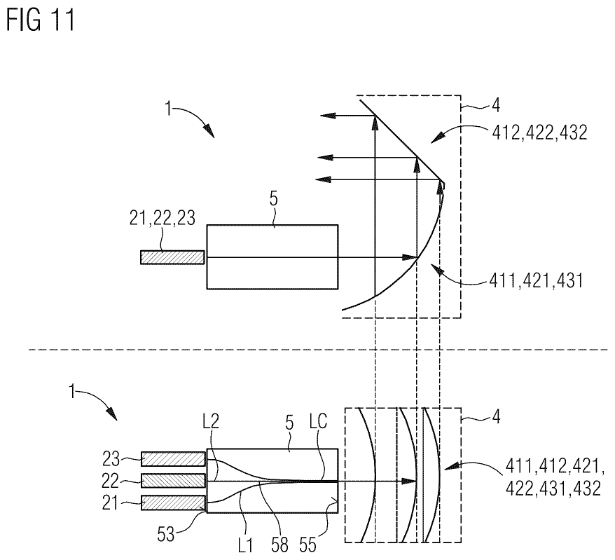

In FIG. 11 it is shown that all the semiconductor lasers 21, 22, 23 are located at the front side 53. In or at a face of the combining optical element 5, there are waveguides 58. By means of the waveguides 58, the beams L1, L2, L3 are merged into the common laser beam LC.

Thus, beam combination can be done with a Planar Lightwave Circuit, PLC, or a Photonic Integrated Circuit, PIC, with directional couplers, for example. Hence, high compactness and compatibility to further PIC elements can be achieved.

Contrary to what is shown in FIG. 11, there can be distance adjustment pieces and/or adhesives as well, similar to what is illustrated in FIG. 9. Further, for example, for path length adaption, the semiconductor lasers 21, 22, 23 does not need to be all placed on the same side of the combining optical element 5.

Otherwise, the same as to FIGS. 8 to 10 may also apply to FIG. 11, and vice versa.

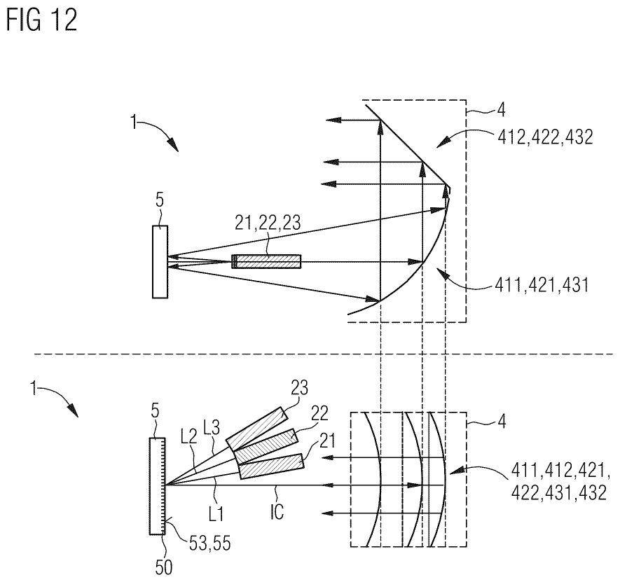

According to FIG. 12, the combining optical element 5 is a reflective optical element. The semiconductor lasers 21, 22, 23 are arranged in a common plane, for example, but with different angles of incidence. The combining optical element 5 comprises an optical structuring 50 at the front side 53 which is in this case simultaneously the exit side 55. The optical structuring 50 is, for example, a grating or a prismatic structure or a metaoptics layer so that different colors are reflected with different angles to enable beam merging. With such an arrangement, high compactness can be achieved.

For example, as in all other embodiments, the semiconductor lasers 21, 22, 23 can be configured for narrow-band emission. For example, a spectral emission width at full width at half maximum, FWHM, of the semiconductor lasers 21, 22, 23 is at most 10 nm or at most 5 nm or at most 3 nm. Hence, the semiconductor lasers 21, 22, 23 are suitable to be handled by gratings or metaoptics, even with some beam divergence.

In the configuration of FIG. 12, the collimated common laser beam LC emitted by the redirecting optical element 4 may run in parallel or approximately in parallel with the laser beams L1, L2 and/or L3 directly after the respective semiconductor laser 21, 22, 23.

Otherwise, the same as to FIGS. 8 to 11 may also apply to FIG. 12, and vice versa.

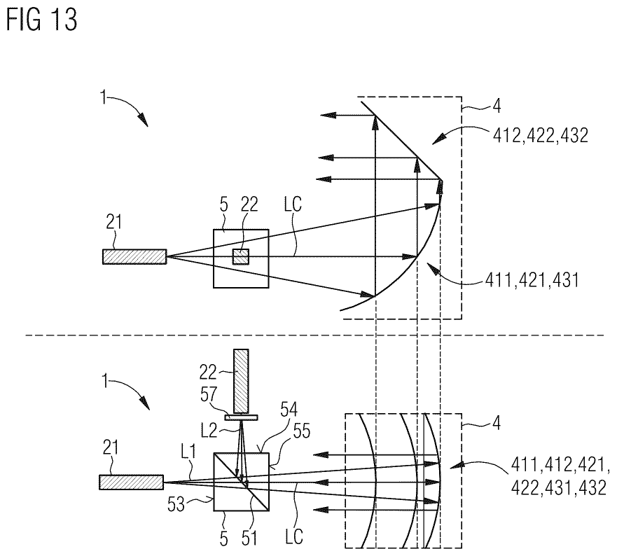

As shown in FIG. 13, beam combination is done by a polarizing beam splitter as the combining optical element 5. Hence, the combining optical element 5 can comprise the first mirror 51 that has a polarization dependent reflectivity. Accordingly, the lasers 21, 22 can be configured to emit the same or also different colors.

Optionally, there is a λ/2 plate 57, also referred to as waveplate. When using such a λ/2 plate 57, the semiconductor lasers 21, 22 can be mounted with the same polarization, relative to the mounting platform, not shown in FIGS. 8 to 13.

With the set-up of FIG. 13, combination of laser beams L1, L2 with similar wavelengths, for example, for high-power laser projection, is possible in order to achieve higher irradiance and/or higher conversion efficiency, for example. Again, there can be distance adjustment pieces and/or adhesives as well, similar to what is illustrated in FIG. 9.

In all FIGS. 8 to 13, all the different kinds of redirecting optical elements 5 as explained in connection with FIGS. 1 to 6, including metaoptics as well as the different possible combinations of plane and curved reflection zones, can be applied. It is possible that different kinds of combining optical elements 5 are combined with each other in a single embodiment, for example, to enable a cascade of more than three laser beams to be combined, especially when using at least one polarizing beam splitter.

In addition to AR/VR applications, the optoelectronic light source 1 described herein can be used to combine laser diodes into a single emission point for projection, laser processing, and related applications. For example, multiple blue laser diodes may be combined through multi-mode waveguide branches as described. The concept of the redirecting optical element 4 can also be used in the opposite way, with a single laser diode providing several coherent or partially coherent outputs. These outputs can be used in various applications, including interferometry. The techniques can also be used to make single mode waveguides, which have special applications where coherence and low optical loss are needed. This includes adding resonators, non-linear structures, and interferometers, for example.

U.S. patent application Ser. No. 17/200,068 refers to an optoelectronic light source and to data glasses. The disclosure content of this application is included by reference.

The invention described here is not restricted by the description on the basis of the exemplary embodiments. Rather, the invention encompasses any new feature and also any combination of features, which includes in particular any combination of features in the patent claims, even if this feature or this combination itself is not explicitly specified in the patent claims or exemplary embodiments.

1. An optoelectronic light source comprising:
a first semiconductor laser configured to emit a first laser beam and arranged on a mounting platform, and
a redirecting optical element configured to redirect the first laser beam, wherein
the redirecting optical element comprises a first primary reflection zone and a first secondary reflection zone,
the first laser beam runs from the first semiconductor laser to the first primary reflection zone and further directly from the first primary reflection zone to the first secondary reflection zone,
directly after the first semiconductor laser the first laser beam has an asymmetric beam cross-section, by means of the redirecting optical element an asymmetry of the beam cross-section of the first laser beam is reduced, and
with a tolerance of at most 45°, directly before the redirecting optical element the first laser beam runs antiparallel relative to the first laser beam directly after the first secondary reflection zone.

2. The optoelectronic light source according to claim 1, further comprising a second semiconductor laser configured to emit a second laser beam and also arranged on the mounting platform,

3. (canceled)

4. The optoelectronic light source according to claim 16, wherein the combining optical element is a transmissive optical element.

5. The optoelectronic light source according to claim 1, wherein optical path lengths of the first and second laser beams from the first and second semiconductor lasers, respectively, to the redirecting optical element are the same.

6. The optoelectronic light source according to claim 16,
wherein the combining optical element conserves a direction of the first laser beam and the first semiconductor laser is arranged on a front side of the combining optical element opposite the redirecting optical element, and
wherein the second semiconductor laser is arranged on a lateral side of the combining optical element running in parallel with the first laser beam within the combining optical element, with a tolerance of at most 30.

7. The optoelectronic light source according to claim 2,
wherein the first laser beam directly runs from the first semiconductor laser to the first primary reflection zone,
wherein, with a tolerance of at most 45°, directly after the first semiconductor laser the first laser beam runs antiparallel relative to the first laser beam directly after the first secondary reflection zone,
wherein the redirecting optical element further comprises a second primary reflection zone and a second secondary reflection zone, the second primary reflection zone and the second secondary reflection zone are configured to reduce a beam asymmetry of the second layer beam and with a tolerance of at most 45°, directly after the second semiconductor laser the second laser beam runs antiparallel relative to the second laser beam directly after the second secondary reflection zone,
wherein after passing the redirecting optical element, the first laser beam and the second laser beam run in a common plane, and
wherein beam diameters of the first laser beam and of the second laser beam at the first primary reflection zone and at the second primary reflection zone amount to at least 0.2 mm so that the redirecting optical element is configured to collimate or focus the first laser beam and the second laser beam with a remaining divergence angle of at most 5°.

8. The optoelectronic light source according to claim 1, wherein at least one of the first primary reflection zone or the first secondary reflection zone is of curved shape.

9. The optoelectronic light source according to claim 1, wherein one of the first primary reflection zone and the first secondary reflection zone is of planar shape.

10. The optoelectronic light source according to claim 1,
wherein both the first primary reflection zone and the first secondary reflection zone are mirrors each having a main curvature and a minor curvature along perpendicular directions, the main curvatures are oriented along main directions perpendicular to one another with a tolerance of at most 30°, and
wherein the corresponding main curvatures and minor curvatures differ from one another by at least a factor of five, in each case a radius of curvature of the main curvature is smaller than that of the corresponding minor curvature.

11. The optoelectronic light source according to claim 1,
wherein the first semiconductor laser is an edge-emitting laser, and
wherein one of the first primary reflection zone and the first secondary reflection zone is configured for fast-axis collimation, and the other one of the first primary reflection zone and the first secondary reflection zone is configured for slow-axis collimation.

12. The optoelectronic light source according to claim 1, wherein the redirecting optical element is a monolithic mirror element.

13. The optoelectronic light source according to claim 1, wherein at least one of the first primary reflection zone or the first secondary reflection zone is a polynomial mirror or a parabolic mirror.

14. The optoelectronic light source according to claim 1, wherein at least one of the first primary reflection zone or the first secondary reflection zone is on average of planar shape and comprises at least one meta-optical structure.

15. Data glasses configured for at least one of virtual reality or augmented reality applications, comprising:
an optoelectronic light source according to claim 2,
an imaging unit downstream of the optoelectronic light source, and
a picture-making element downstream of the imaging unit,
wherein the optoelectronic light source is configured to illuminate the picture-making element by means of the imaging unit so that a picture can be produced by means of the picture-making element.

16. An optoelectronic light source comprising:
a first semiconductor laser configured to emit a first laser beam and arranged on a mounting platform,
a second semiconductor laser configured to emit a second laser beam and also arranged on the mounting platform,
a redirecting optical element configured to redirect the first laser beam, and
a combining optical element directly after the first and second semiconductor lasers and directly before the redirecting optical element,
wherein
the redirecting optical element comprises a first primary reflection zone and a first secondary reflection zone,
the first laser beam runs from the first semiconductor laser to the first primary reflection zone and further directly from the first primary reflection zone to the first secondary reflection zone,
directly after the first semiconductor laser, the first laser beam has an asymmetric beam cross-section, by means of the redirecting optical element an asymmetry of the beam cross-section of the first laser beam is reduced,
with a tolerance of at most 45°, directly before the redirecting optical element the first laser beam runs antiparallel relative to the first laser beam directly after the first secondary reflection zone, and
the combining optical element is configured to merge the first and second laser beams into a common laser beam so that the common laser beam the first and second laser beams.

17. The optoelectronic light source according to claim 5 wherein the common laser beam is formed within the combining optical element, and wherein the combining optical element comprises a first mirror which is an internal mirror and which is configured to transmit the first laser beam and to reflect the second laser beam.
